(19) United States
(12) Patent Application Publication
(10) Pub. No.: US 2011/0085241 A1
(43) Pub. Date: Apr. 14, 2011

(54) TRANSMISSIVE OPTICAL MICROSTRUCTURE SUBSTRATES THAT PRODUCE VISIBLE PATTERNS

(76) Inventors: Ken G. Purchase, Morrisville, NC (US); Robert M. Soule, III, Rougemont, NC (US)

(21) Appl. No.: 12/901,754

(22) Filed: Oct. 11, 2010

Related U.S. Application Data
(60) Provisional application No. 61/302,279, filed on Feb. 8, 2010.
(60) Provisional application No. 61/251,141, filed on Oct. 13, 2009.

(51) Int. Cl. G02B 5/02; G03F 7/20; G03F 7/00

(52) U.S. Cl. 359/599; 430/322; 430/2

(57) ABSTRACT

A light transmissive structure such as a light diffuser includes a substrate having optical microstructures. The optical microstructures include at least one feature that varies across the substrate, so as to produce a visible indicia relative to a viewer of the light transmissive structure. Related diffusers and methods of fabrication are also described.

### CROSS-REFERENCE TO RELATED APPLICATIONS

This application claims priority to and the benefit of U.S. Provisional Application No. 61/302,279, filed Feb. 8, 2010, entitled Optical Films With Visible Patterns, and U.S. Provisional Application No. 61/251,141, filed Oct. 13, 2009, entitled Optical Films With Visible Patterns, assigned to the assignee of the present invention, the disclosures of both of which are hereby incorporated herein by reference in their entirety as if set forth fully herein.

### BACKGROUND

This invention relates to lighting systems and, more particularly, to transmissive optical elements that are used in lighting systems.

Lighting systems are commonly used for many lighting/illumination applications, such as general purpose illumination, backlights, signals and displays. Lighting systems generally include one or more light sources. A diffuser is generally provided to diffuse the light that is emitted from the light source, so as to homogenize the light and reduce direct visibility of the light source to a viewer. In many applications, multiple light sources, such as multiple Cold Cathode Fluorescent (CCFL) bulbs, multiple Light Emitting Diodes (LEDs) and/or multiple incandescent bulbs are used, and it may be desirable for the diffuser to also homogenize the light from the multiple light sources. In other lighting systems, a diffuser need not be provided, but a transmissive optical substrate may be provided between the light source(s) and the viewer for various purposes.

### SUMMARY

Light diffusers according to various embodiments described herein include a substrate having a plurality of diffusing optical microstructures therein and/or thereon. The plurality of diffusing optical microstructures include at least one feature that varies across the substrate so as to produce a visible indicia relative to a viewer of the light diffuser. In some other embodiments, the plurality of diffusing optical microstructures include at least one feature that varies deterministically, randomly and/or pseudorandomly across the substrate, so as to diffuse the incoming light. In other embodiments, the light diffuser is also configured to diffuse radiation from a plurality of light sources having predetermined spacing therebetween, and the plurality of diffusing optical microstructures also include at least one feature that varies across the substrate as a function of the predetermined spacing between the plurality of light sources.

In some embodiments, the optical microstructures have a dimension along the substrate that is less than about 100 μm, and the visible indicia may have a dimension along the substrate that is greater than about 100 μm. In some embodiments, millimeter, centimeter and/or larger-sized visible indicia may be provided. The optical microstructures may comprise a polymer in some embodiments. In other embodiments, the at least one feature that varies across the substrate comprises a discrete and/or continuous variation of a size and/or a shape of the plurality of diffusing optical microstructures. In other embodiments, the visible indicia may produce a plurality of discrete and/or continuous levels of brightness that can provide, for example, grayscale shading and/or a continuously varying shading, relative to the viewer.

In some embodiments, the plurality of diffusing optical microstructures are on the substrate. In some of these embodiments, the light diffuser may further comprise a cladding layer on the plurality of diffusing optical microstructures that provide a smooth outer surface on the plurality of diffusing optical microstructures. The refractive index of the cladding layer is different from that of the diffusing optical microstructures in some embodiments.

Still other embodiments described herein provide light transmissive structures that need not be diffusing. These light transmissive structures may comprise a substrate including a plurality of optical microstructures therein and/or thereon. The plurality of optical microstructures also include at least one feature that varies across the substrate, so as to produce a visible indicia relative to a viewer of the light transmissive structure. The at least one feature may comprise a size and/or a shape of the plurality of optical microstructures, the optical microstructures themselves may have a dimension along the substrate that is less than about 100 μm and the visible indicia may have a dimension along the substrate that is greater than about 100 μm. Gray scale and/or continuously varying brightness may also be provided.

Smoothly varying diffusion may also be added to these light transmissive structures to additionally equalize source brightness. For example, in some embodiments, the light transmissive structure may be further configured to diffuse radiation from a plurality of light sources having predetermined spacing therebetween by including at least one feature in the plurality of optical microstructures that varies across the substrate as a function of the predetermined spacing between the plurality of light sources. The optical microstructures may also include at least one feature that varies deterministically, randomly and/or pseudorandomly across the substrate so as to diffuse incoming light, according to other embodiments.

Light transmissive structures may also be fabricated according to various embodiments described herein. These light transmissive structures may be fabricated by imaging into a photoimageable material an image of a plurality of optical microstructures that include at least one feature that varies across a plurality of optical microstructures. The photoimageable material that was imaged is then used, directly or indirectly, to replicate a plurality of optical microstructures in and/or on a substrate. The plurality of optical microstructures include at least one feature that varies across the substrate, so as to produce a visible indicia relative to a viewer of the light transmissive structure. In some embodiments, the light transmissive structure comprises a diffuser. In other embodiments, diffusion need not be provided.

In some embodiments, imaging takes place by scanning laser (continuous-wave or pulsed) across the photoimageable material. The laser defines the image of a plurality of optical microstructures that include at least one feature that varies across the plurality of optical microstructures. In other embodiments, imaging takes place by holographically imaging into a photoimageable material the image of a plurality of optical microstructures that include at least one feature that varies across the plurality of optical microstructures.

### BRIEF DESCRIPTION OF THE DRAWINGS

FIG. 1A is a perspective view of a light transmissive structure such as a diffuser according to various embodiments described herein.

FIGS. 1B and 1C are enlarged cross-sectional views of areas 103 and 104, respectively, of FIG. 1A.

FIG. 2 is a simplified cross-sectional view of a luminaire according to various embodiments described herein.

FIG. 3 illustrates a plurality of optical microstructures including at least one feature that varies across a substrate, so as to produce a visible indicia relative to a viewer according to various embodiments described herein.

FIG. 4 is a flowchart of methods of fabricating light transmissive structures, such as light diffusers, according to various embodiments described herein.

### DETAILED DESCRIPTION

Light transmissive structures are used in many fields. One field is that of diffusers for lighting. LED, fluorescent, and other high-efficiency lighting technologies are becoming more important in luminaires (lighting fixtures) for residential, public, commercial and/or other environments. One important element of many luminaire designs is the diffuser. A diffuser, in the form of a film, plate, or other formed element, collectively referred to herein as a “substrate”, may be used to create or control how the light spreads from the luminaire to the viewer and/or to control (e.g. obscure) the visibility of the light sources within the luminaire from the viewer.

In particular, Light Emitting Diode (LED) based luminaires may have a stringent requirement for obscuring the light sources, to completely hide the point-like LED sources from the viewer. LED luminaires typically have multiple high-brightness LED's, which if viewed without diffusion are uncomfortably bright. For aesthetic reasons, it is generally desirable that the individual LED sources be substantially invisible to a viewer of the luminaire. Diffusers, including films or plates with surface texture and/or volume diffusion are typically used to smooth out the appearance of the individual LED's.

Bright View Technologies (BVT) manufactures optical structures, including lighting diffusers, that comprise microscopic surface texture created on a substrate such as PET, glass, acrylic or polycarbonate. The surface texture includes pseudo-random, random and/or non-random patterns of optical microstructures created in a photoresist and replicated into transparent polymers on a substrate. The surface texture of optical microstructures may have typical feature dimensions on the order of one to tens (or sometimes hundreds) of microns. However, some diffusers, such as holographic diffusers, may have spatial feature dimensions that are additionally as small as the order of 0.1 microns. When used for diffusers, such surface texture typically has a dimension along the substrate that is less than about 100 microns, for example in the 5-30 micron spatial scale. The microstructure features may be defined in advance or may be generated in real time as they are exposed (generally by a modulated laser) into a photosensitive material. Such features may be pseudo-random, in which an algorithm generates features over some area using a pre-defined algorithm. Such area may be the entire photosensitive material, or may be a small area (such as 2 mm×2 mm) that is repeated by tiling across the whole photosensitive material. Features may also be deterministic, such as a diffraction grating, microlens, or other features. Features may also be an algorithmically, randomly or pseudorandomly varied collection of such features, such as microlenses of varying focal length or size.

The substrate may optionally have a degree of volumetric diffusion, for example caused by micro- or nano-particles (such as TiO₂, silica and/or ground polymer particles) embedded in the substrate material. The substrate may optionally have another treatment on the opposite side of the microscopic textures. This other treatment may be a coating with cloudy (diffusive) appearance such as microscopic beads or particles (such as TiO₂, silica and/or ground polymer particles) imbedded in a polymer matrix, or other such diffusive coating.

These diffusers can do an excellent job of hiding the LED sources and creating a very smooth appearance. When tested with normally-incident collimated light, these diffusers generally diffuse light into some desired angular distribution (such as circular or elliptical spanning desired angles from the axis of the diffuser). In use, the diffusers may be illuminated by collimated, diffuse, or other distributions of light. Often the diffusers are illuminated by light sources in a luminaire, such as fluorescent tube(s) or LED's.

During use, light generated by the light sources in the luminaire enters the diffuser. Some of this light is transmitted, being diffused in a desired manner, and some portion of the light is reflected by the diffuser back into the luminaire. Desirably, the diffuser does not substantially absorb any of the light. Light that is reflected back into an appropriately-designed luminaire is substantially reflected (possibly through multiple bounces or reflections in the luminaire) back toward the diffuser. In this manner the combination luminaire/diffuser maintains high efficiency (total light emitted compared to total light generated) while producing the desired levels of diffusion.

BVT also has the ability to clad substrates with surface texture—i.e. to create a surface texture in a material with a given refractive index, and then to embed this surface texture in a material of different refractive index. In such cases, flat structures can be made that have optical function despite having no surface relief on the outer surfaces. This may be advantageous in various applications, such as when the end user intends to laminate the structure between other materials. It should be noted that a structure with surface texture on an outer surface may be regarded as a case of a clad structure where the material of different refractive index is air, which has a refractive index of about 1.

BVT also has the ability to create surface textures on substrates (including films) that have been treated or coated with another material, such as a diffusive material (microspheres or powders or ground plastic), carbon black, metals such as silver or aluminum, white or other paint, etc.

BVT also has patents and patent applications to laser treat an optical element to create holes in such materials whose location and size are determined by the optical action of the surface texture upon the incoming laser. For example, microlenses can be created on one surface of a substrate, and laser exposure is used to create holes in a black coating on the opposite side of the substrate which are aligned with the foci of the microlenses. Laser creation of holes are described, for example, in U.S. Pat. No. 6,967,779, entitled Micro-Lens Array With Precisely Aligned Apertures Mask and Methods of Producing Same; U.S. Pat. No. 7,394,594, entitled Methods For Processing A Pulsed Laser Beam To Create Apertures Through Microlens Arrays; and U.S. Patent Application Publication No. 2008/0084611 entitled Methods and Apparatus for Creating Apertures Through Microlens Arrays Using Curved Cradles, and Products Produced Thereby, assigned to the assignee of the present invention, the disclosures of all of which are incorporated herein by reference in their entirety as if set forth fully herein.

BVT also has a published patent application in which microstructures on a substrate are varied over macroscopic areas in relation to the light sources illuminating that substrate, for the purpose of obscuring, smoothing, equalizing, or otherwise responding to the light sources. See application Ser. No. 12/506,915, filed Jul. 21, 2009, entitled Optical Diffusers With Spatial Variations to Purchase et al., corresponding to U.S. Patent Application Publication No. 2010/0039808, assigned to the assignee of the present invention, the disclosure of which is incorporated herein by reference in its entirety as if set forth fully herein.

A diffusion film is also made by Luminit of Torrance, Calif. See luminitco.com. Luminit makes holographic diffusers, in which a holographic exposure is used to create random surface texture on alight-sensitive material, and subsequently this surface texture is replicated into a polymer layer on a substrate. The surface texture material and/or substrate may have additional volumetric diffusion by way of micro- or nano-particles embedded in the surface texture material or substrate.

Other diffusers are made by Fusion Optix, Inc. Woburn, Mass. See fusionoptix.com. According to their website, these diffusers use “tiny structures in the bulk of the film, similar to microlenses that direct and shape light into a particular pattern.” These may be multilayer structures with embedded features that create a volumetric diffusion.

Yet other diffusers are marketed by Lexalite International Corporation. See, for example, U.S. Pat. Nos. 5,743,634; 5,967,648 and 6,550,930.

Diffusers used in LED luminaires are generally spatially uniform, in that the average degree of diffusion of light, reflection, and transmission in a first macroscopic area (e.g. one square inch of surface) is substantially the same as that in another area spatially separated from the first. Thus when viewed by the unaided human eye, the diffuser appears to be devoid of texture. Note that on the scale of about 1 mm, some fine texture may be visible as a result of the microscopic surface or volumetric variations, but in general the diffuser looks homogeneous from normal viewing distances.

A different type of diffuser is typically used in fluorescent lighting fixtures, and sometimes in LED and/or other fixtures (common, for example, in office environments). A very common type of diffuser is a clear polymer (such as acrylic) that has formed surface features (such as a close-packed array of inverted pyramids) of large (up to a few mm to 1 cm and beyond) spatial dimension. These diffusers are often referred to as “prismatic” or “microprismatic”. Microprismatic diffusers typically have features on the order of 0.5 to 5 mm in size, and prismatic diffusers generally have larger features. Some vendors of these types of diffusers include Jungbecker (jungbecker.de), Rotuba (rotuba.com), A.L.P. (alplighting.com), Plaskolite (plaskolite.com), and Evonik (using the brand name Plexiglas, plexiglas.de/product/plexiglas/en/products/Pages/default.aspx).

BVT has the ability to modulate virtually any properties of the microscopic surface texture in a desired manner that varies over the surface of an optical element. Such optical element can be film, plate, dome, bulb, or other formed element, and performs some optical function. In embodiments of the present invention, some property of the microscopic surface texture is modulated over a macroscopic area in such a way as to be visible to the human eye, i.e., by a viewer of the light diffuser during its typical use. This includes superimposing a macroscopic pattern or image (such as an image of a flower, or a repeating pattern of dots or circles) on the microscopic pattern. This further includes the use of such macroscopic patterns for aesthetic purposes. These patterns or images that are visible to a viewer are collectively referred to herein as “indicia”.

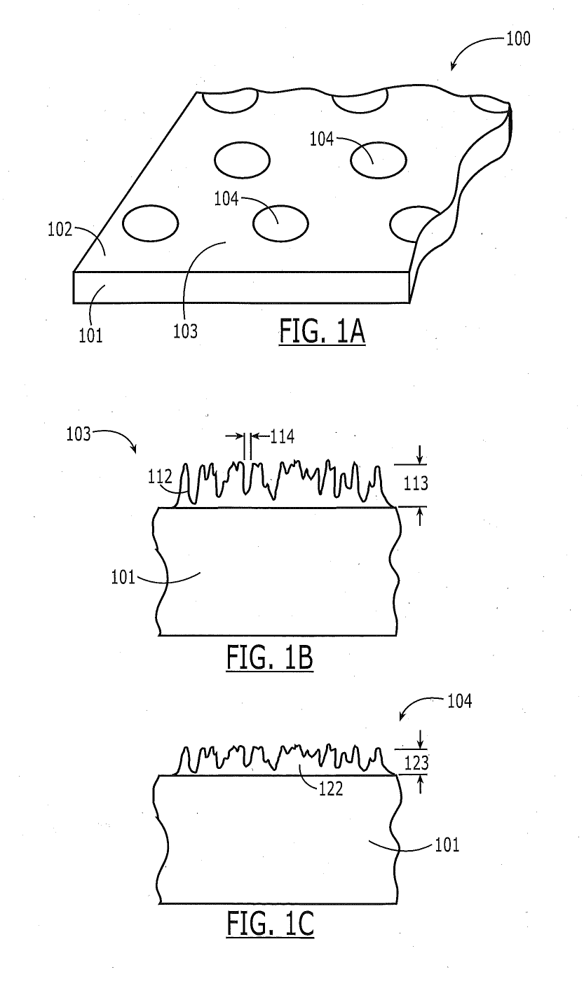

In the embodiments of FIG. 1, an optical structure 100, such as a light diffuser, comprises a substrate 101 which includes a microscopic surface texture 102. Details of the microscopic surface texture are not explicitly depicted because they are generally invisible to the human eye, or hard to see. This microscopic surface texture is varied on a macroscopic dot pattern in which dots 104 of diameter 2 mm are separated by about 8 mm. FIG. 1B shows a cross-section of the structure in an area 103 not covered by a dot 104. Substrate 101 is provided with a surface texture 112 which varies in a pseudo-random fashion with approximate feature sizes of about 10 microns in the in-plane dimensions 114 (i.e., along the substrate 101). The height 113 of the surface texture in this area is about 15 microns. FIG. 1C shows a cross-section of the structure in an area covered by a dot 104. Substrate 101 is provided with a surface texture 122 which also varies in a pseudo-random fashion with approximate feature sizes of about 10 microns in the in-plane dimensions. The height 123 of the surface texture in this area is about 9 microns. Due to the different average heights, the angular diffusivity of the dot pattern differs between the area 104 within a dot and an area 103 outside of a dot, such that when viewed from at least one viewing angle, the dot pattern is visible to the human eye.

Accordingly, FIGS. 1A-1C illustrate a light diffuser 100 according to various embodiments described herein that comprises a substrate 101 including a plurality of diffusing optical microstructures 112, 122 therein and/or thereon. The plurality of optical microstructures include at least one feature, here height 113, 123, that varies across the substrate 101, so as to produce a visible indicia, here dots 104 and interstitial space 103, relative to a viewer of the light diffuser. Embodiments of FIGS. 1A and 1B also illustrate that the plurality of diffusing optical microstructures 112, 122 also include at least one feature (the feature size and shape of the optical microstructures 112, 122) that varies deterministically, randomly and/or pseudorandomly across the substrate 101.

In embodiments of FIG. 2, the light diffuser 100 with dot pattern 104 of FIG. 1 is included as the diffuser 204 in an LED luminaire 200. The luminaire 200 has LED light sources 201 enclosed within a housing 202 such as a metal container with an inside surface painted with a highly-reflective white coating 203. In operation, the light generated by the LEDs 201 appears to be radiating from the diffuser 204, and the individual LED light sources 201 are not visible. A viewer on the opposite side of diffuser 204 than the LEDs 201 (represented by an eyeball 205) at appropriate viewing angles and at normal viewing distances perceives the dot pattern on the diffuser 204. Other light sources also may be used.

Accordingly, embodiments of FIG. 2 also illustrate a light diffuser that is configured to diffuse radiation from a plurality of light sources such as LEDs 201 having predetermined spacing therebetween. The plurality of diffusing optical microstructures 112, 122 also include at least one feature that varies across the substrate as a function of the predetermined spacing between the plurality of light sources 203, as described in greater detail in the above cited application Ser. No. 12/506,915.

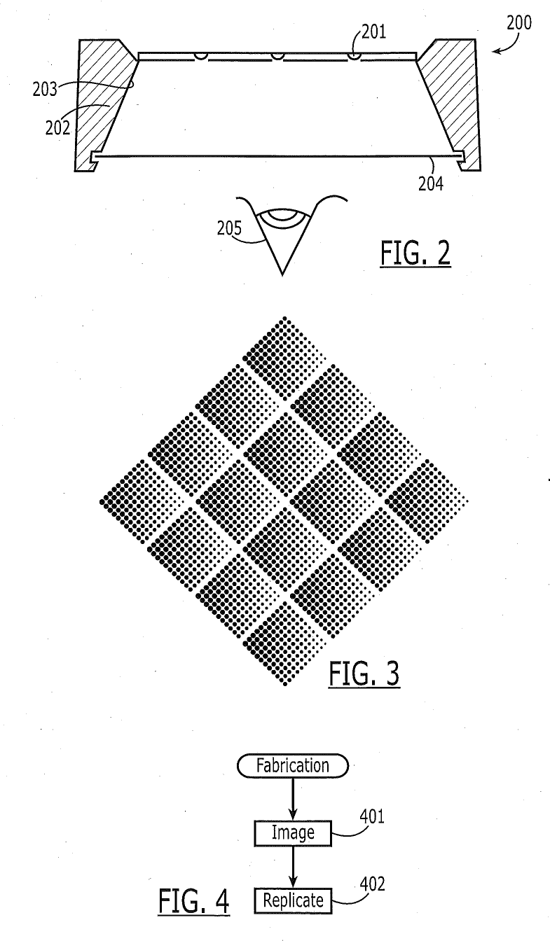

FIG. 3 depicts an example of a continuous-tone macroscopic pattern, a repeating pattern of squares with varying shading that may produce a perceived three-dimensional look. The squares are about 5 mm in dimension. The peak-to-valley height of the microscopic pattern varies monotonically and continuously from the brightest point of the pattern to the darkest point of the macroscopic pattern. Accordingly, FIG. 3 illustrates embodiments wherein at least one feature provides a plurality of levels of brightness, such as grayscale levels, or a continuously varying brightness, relative to a viewer.

In various embodiments of the present invention, modulation of the microscopic surface pattern between one macroscopic position and another results in a change in the optical response of the optical element between these positions. This may be a change in the degree of diffusivity of the optical element, or more generally a change in the bidirectional transmittance distribution function (BTDF) of the optical element. The BTDF generally describes how any light incident upon the optical element is transmitted, reflected, scattered, diffused, and/or absorbed by the optical element. The BTDF can be used in optical modeling software to predict how a given optical structure will act upon light. The change in optical response may also include a change in the focal length of microlenses, a change in diffraction angle and/or a change in any other optical property of the optical element.

Such changes are desirably of sufficient magnitude to be viewable by the unaided human eye from some viewing position. Various embodiments of the invention include devices or products that contain such an optical element, and thus the changes are visible to the human eye when viewing the device. In one example, an optical element with macroscopic variation of microscopic patterning can be used in a luminaire which, when viewed from a certain angle(s), shows the desired image or pattern.

Having luminaires for which the output light shows a texture (picture or abstract pattern) has at least several potential advantages:
For the purpose of aesthetics, various patterns can be used to be visually appealing. Abstract patterns may be thought to give a more sophisticated look than a simple uniform surface.
Patterns with fine detail can hide defects that may arise in the manufacturing process, making some unacceptable defects become acceptable to a customer, thus increasing manufacturing yields. They can also reduce the appearance of debris (dust, insects, etc.) that get into light fixtures over time, when compared to uniform diffusers.
Desirable patterns can be placed in luminaires to achieve artistic or aesthetic goals, such as matching lighting to room or wall decorations, inserting corporate logos, sports team logos, etc. Often such patterns can be customized to the desires of a given customer, e.g. images of ferns and tropical plants for lighting fixtures in a restaurant whose décor has a tropical or rainforest theme.

Examples of indicia (images or patterns) suitable for use in various embodiments of the invention include, but are not limited to:
Repeating patterns of dots, circles, squares, hexagons, and the like, possibly with shading (grayscale or continuous) to give a three-dimensional appearance, over the surface of the optical element.
Random patterns of such shapes over the surface of the optical element, such as an image of the randomly packed circular dots that are commonly on the surface of a basketball.
Circularly or radially symmetric patterns (which may be desirable for round lights such as typical “can” light fixtures). Examples include a compass rose, flowers, spirals, lines radiating from a central point, etc.
Images or patterns that simulate natural or man-made surfaces such as wood, stone, granite, marble, fabric, marbled paper, fur, foliage, honeycomb, ocean waves, clouds, stars, mother-of-pearl, etc.
Images or patterns that are generated by a computer including random noise with any predetermined distribution, repeating or tiled random patterns, swirled patterns, etc.
Geometric shapes.
Stripes or other linear patterns.
Text, numbers, or other identifying characters.
Gradients or areas of gradients. Such patterns may give a three-dimensional effect.
Any of the textures that are used on ceiling tiles for suspended ceilings. Matching a ceiling tile may be desirable for environments with suspended ceilings and lighting fixtures.
Any patterns that have been printed on fabrics used in clothing, upholstery, window treatments, etc., or wallpapers or other decorative items.

Other embodiments of this invention include systems and methods for writing the microstructures of this invention using a light source in photosensitive media. There are several embodiments:
In some methods and systems, the microstructures of various embodiments of this invention are created using a modulated, substantially focused laser beam, and appropriate optical and/or mechanical scanning equipment, such that the laser can address the entire desired area of a photosensitive material. A control system produces the signals that modulate the laser beam according to the desired pattern of this invention. Accordingly, as shown at Block 401 of FIG. 4, a light transmissive structure may be fabricated by imaging into a photoimageable material an image of a plurality of optical microstructures that include at least one feature that varies across the plurality of optical microstructures.
In some embodiments, the optical diffuser may include an optically transparent sheet having optical microstructures replicated on a surface. The microstructures may be produced by replicating a master, as illustrated at Block 402 of FIG. 4. For example, an optical diffuser can be made by replication of a master containing the desired shapes as described in U.S. Pat. No. 7,190,387 to Rinehart et al., entitled Systems And Methods for Fabricating Optical Microstructures Using a Cylindrical Platform and a Rastered Radiation Beam; U.S. Patent Application Publication No. 2005/0058948 A1 to Freese et al., entitled Systems and Methods for Mastering Microstructures Through a Substrate Using Negative Photoresist and Microstructure Masters So Produced; and/or U.S. Pat. No. 7,192,692 to Wood et al., entitled Methods for Fabricating Microstructures by Imaging a Radiation Sensitive Layer Sandwiched Between Outer Layers, assigned to the assignee of the present invention, the disclosures of all of which are incorporated herein by reference in their entirety as if set forth fully herein. The masters themselves may be fabricated using laser scanning techniques described in these patents and published application, and may also be replicated to provide diffusers using replicating techniques described in these patents and published applications.
In other methods and systems, laser holography, known in the art, is used to create a holographic pattern that creates the desired microstructure in a photosensitive material. The indicia is added by spatially modulating one or more of the laser beams, exposing through a patterned mask and/or by pre- or post-exposing the desired macroscopic structure in the photosensitive material as described below.
In other methods and systems, projection or contact photolithography, such as used in semiconductor, display, circuit board, and other common technologies known in the art, is used to expose the microstructures into a photosensitive material.
In other systems/methods, laser ablation, either using a mask or using a focused and modulated laser beam, is used to create the microstructures including the indicia in a material.
In other systems/methods of this invention, the indicia can be superimposed in the actual surface relief of a diffuser film or plate for a luminaire. The angular spread, diffusivity, and brightness of light in a luminaire with a BVT diffuser is a function of the microscopic surface texture that is applied to that diffuser, including being a function of the peak-to-valley height of the surface texture. BVT has the capability to modulate this texture (such as by changing the peak-to-valley height of feature(s) in the texture) across the extent of a master, such that the one or more optical properties (such as angular spread of the diffusion) vary from place to place, in the form of the desired macroscopic indicia. A specific example of this would be to use one of BVT's existing lighting diffuser products which is substantially uniform in the macroscopic scale and superimpose a macroscopic image of a flower defined by a bitmap file as indicia. In these embodiments, the peak-to-valley height of the structures at a given location across the diffuser is changed to be proportional to the local brightness value of the desired image that desired location. Desired patterns in the luminaires can be achieved in many ways:
The microscopic surface texture (i.e., at least one feature of the optical microstructures) can be changed from one macroscopic locality to another in a continuous manner proportional to the desired indicia in ways that include but are not limited to:
   Changing the structure height (or peak-to-valley height) of the microscopic structures (e.g. microlenses) in proportion to the desired image.
   Changing the feature size (e.g. microlens diameter) of the microscopic structure in response to the desired image.
   Changing the feature shape, orientation, size, height, etc.
   Changing optical parameters of the surface structure, such as lens focal length or diffraction grating pitch.
   Changing the parameters (discretely or continuously) used in equations or algorithms that define the surface texture.
The microscopic surface texture can be changed in discrete steps (rather than continuously), and create the desired macroscopic image or pattern in ways that include but are not limited to:
   Changing between a multiplicity of different (related or unrelated) microscopic surface textures from one location to another.
   Changing between two (or more) different microscopic surface textures in a halftone pattern (such as used in the printing industry to create continuous tones from one ink color) from one location to another. The halftone screen pattern would be on a spatial scale between that of the microscopic surface texture and that of the macroscopic image or pattern.
   Changing between two (or more) different microscopic surface textures in a dithered pattern (such as commonly used by inkjet printers to generate continuous tones from one ink color) from one location to another. Again, the spatial scale of the dithering would be on a spatial scale between that of the microscopic surface texture and that of the macroscopic image or pattern.
In some cases BVT may have two or more engineered replicated surfaces (including front, back, and embedded surfaces of an optical elements or optical elements bonded together) and indicia can be on one or more of these surfaces.
In other embodiments of this invention, a diffuser may be created according to application Ser. No. 12/506,915 (cited above) in which the microscopic surface structure is varied across the surface of the diffuser to produce a more uniform appearance in a luminaire (such as to limit variations in brightness over the surface of a light that has multiple fluorescent tubes or multiple LED's), and additionally according to various embodiments of the present invention a texture of macroscopic dots or other visible indicia is further superimposed upon this diffuser by further variation of the microscopic surface texture.
In other systems/methods, multiple exposures (pre- or post-exposure) of a photosensitive material can be used to create the indicia superimposed on the microscopic diffuser features. For example, two separate exposures are used on the same photoresist, one using BVT's above cited patents to create microstructures, and another using any of a variety of techniques to create macrostructures, either before or after the microstructure exposure. One example technique for the macrostructure exposure is using a modulated scanning laser before or after the writing of the microstructures such that both structures are superimposed in the photoresist. Another example technique for the macrostructure exposure is using a patterned film (such as black ink on a transparent film often used in the silkscreen and printing industries) in contact with (or near) the photoresist film stack, and using a flood exposure, such as UV light from a distant UV light bulb to expose the desired features. In these embodiments, nonlinearities in the photoresist may exist and may produce different results depending on the order and intensity of the exposures.
Similarly (but with different overall optical effect) the pattern can be superimposed on the back surface of a diffuser (the opposite surface of BVT's engineered textured surface). Some of BVT's diffuser products have diffusive materials on the back, such as scattering material (e.g. TiO2 or plastic or dielectric particles imbedded in a polymer binder), or surface texture. This backside diffusion material could be modulated in the desired macroscopic pattern without affecting the microscopic pattern on the other side. One specific method of creating such an effect might be inkjet, gravure, or other printing of a scattering or white material (such as thin white paint, or polymer impregnated with micro- or nano-particles) in the desired macroscopic pattern. Another specific method may be silk-screening such diffusive material in the desired image.
Backside printing need not be limited to white ink or clear diffusive materials. One can use a variety of techniques (particularly inkjet printing) to print colored patterns, either one color or multiple colors, on the back (or front) of the diffuser, to achieve desired effects. Generally, in these embodiments, it may be desirable to limit this to small amounts of colorant, so as to reduce or minimize loss (absorption of light energy) that would negatively impact the efficiency of the luminaire.

It is often desirable that any of these techniques have reduced or minimal effect on the efficiency of the luminaire, which means that simple absorbers (black ink or substantial color ink) may be undesirable. However, it is also possible that in certain cases the desire for color may outweigh the desire for efficiency. It is also generally desirable to maintain the “lamp hiding” or concealment of the LED's, so any macroscopic patterning that negatively impacts the hiding of the LED's by reducing the effectiveness of the microscopic diffuser pattern may also be undesirable.

In other embodiments, multiple images may be superimposed, in which each image modifies a different aspect or parameter of the microscopic texture. In this way, it is possible to have different textures or images superimposed on the same diffuser that are each visible from different viewing angles or under different conditions. In one example, a microscopic surface texture is created which contains independent horizontally-varying and vertically-varying components that can be mathematically superimposed to create the desired diffuser. A first macroscopic image is used to modulate the horizontal component across the optical element, and a second macroscopic image is used to modulate the vertical component across the optical element, and at each position on the optical element, the modulated horizontal and vertical components are superimposed according to the desired mathematical function.

In other embodiments, the compound macroscopic/microscopic surface texture of this invention is generated on one material, and then encapsulated in another material of different refractive index. In this way, an optical element is created that may have flat outer surfaces, and yet still retain some effect from the embedded optical surface between the two materials of different refractive index. This effect may be stacked in many layers, and/or combined with surface textures on one or more of the external surfaces. Any one or more of the textures may have superimposed macroscopic patterns of the present invention.

In other embodiments, the compound macroscopic/microscopic surface texture of the present invention is produced on a substrate that has a coating on the opposite surface of the substrate. The coating may be reflective (such as a metal like aluminum or silver), absorptive (such as carbon black), diffusive (such as thin white paint), or opaque (such as thick white paint), etc. In further embodiments, the embodiments above are subjected to BVT's laser treatment using an infrared (IR), ultraviolet (UV), visible, or other laser, to create features (holes, blisters, burns, etc.) in the coating layer. Such a film may have the effect of collimating light, or allowing light or an image to only be visible from predetermined angle(s).

Application areas for various embodiments of this invention include but are not limited to:
Lighting: luminaires as discussed herein. These can include but are not limited to luminaries involving incandescent lights, halogen lights, arc lights, high-intensity discharge lights, fluorescent lights (compact fluorescent bulbs, fluorescent tubes, etc.), LED's, electroluminescent lights, Organic LED's, lasers, candles, etc.
In other embodiments, the diffuser need not be spaced apart from the lighting sources, but, rather, can be incorporated into the lighting source itself. For example, in Organic LED (OLED) lighting sources, a luminaire according to any of the embodiments described herein may be added as an outermost and/or intermediate layer of the OLED array itself.
Use in direct or indirect natural light, such as with skylights, windows, solar tube lights, fiber optic lights, etc.
Architectural Films (diffuse windows, skylights, mirrors, wall treatments, artwork, etc.) which may be illuminated by artificial, or natural light, or may be substantially unlit, only visible via ambient light from other sources.
Security/Authentication tags: In certain embodiments, the visual effect of various embodiments of this invention may be very hard to duplicate or copy. In such cases, the invention could be used as a security or identification tag to certify genuine goods, or differentiate genuine goods (such as software) from copies that may be illegal or counterfeit. One example is in the use of a surface texture on a material of one refractive index embedded in a material of a second refractive index as mentioned above. It may be difficult or even impossible to make a mold of such encapsulated surface texture, making it difficult for a counterfeiter to replicate the security tag. Macroscopic patterns on the security tag may include but are not limited to text and pictures identifying the item to which the tag is affixed.
Partially-reflecting or absorbing mirrors or panels that have one appearance when viewed from one side, and a different appearance from the other side.
Displays: patterned films may be useful in certain application-specific displays. Examples may include borders around displays that have a different brightness or viewing angle, displays with permanent features such as the 7-element digits on a digital clock display, etc.

Other embodiments of the present invention provide systems and methods for modulating the properties of the microstructures during their creation in order to achieve a macroscopic pattern. In some embodiments, the desired effects of the macroscopic pattern are mathematically applied to the microscopic pattern before any microstructures are physically created. The results of this pre-generation step are stored in a form of computer memory, such as RAM, flash memory and/or magnetic media in compressed and/or uncompressed form. During the physical creation of the microstructures (such as by a modulated, focused laser system), this memory is addressed according to location on the substrate in order to define the structure at that location in the substrate.

In some embodiments, the minimum resolution of the microscopic surface texture may be on the order of 0.5 to 5 microns for a desired optical function. Moreover, the minimum resolution of the macroscopic surface texture for a textured optical substrate may be on the order of 0.5 to 5 mm, depending on viewing distance. In other embodiments, the macroscopic visible indicia may have a dimension along the substrate that is greater than about 100 μm and, in some embodiments, on the order of millimeters, centimeters and/or up to about a meter or more. An uncompressed 16-bit grayscale bitmap file representing the microscopic surface texture over a large substrate may be quite large (for example, up to 2 Terabytes for a 1 meter square substrate with 1 micron resolution). However, in many cases the same optical function can be achieved by creating a small microscopic surface texture (such as 5 mm×5 mm) and tiling it across the area of the substrate. Such tiling may be advantageous because of reduced memory requirements. For the case of the macroscopic surface texture, the memory requirements may be much less stringent (for example, up to 2 megabytes for a 1 meter square substrate with 1 mm resolution).

For some applications, it may be impractical to pre-generate and store the combined macroscopic and microscopic pattern at the full microscopic resolution due to the large amount of pre-generated data that would be required. In other embodiments of the invention, only the properties of a subset of the surface texture are stored in memory before beginning to physically create the first microstructures. In this case, the full microstructure including both macroscopic and microscopic components) need only be computed for some appropriately small area in time for that area to be physically created. The system continues to calculate and store the modulated properties of the next microstructures or small areas of microstructures to be physically created. Once the system has physically created the microstructures represented by a given small area of data in memory, the data can be discarded. This technique of generating the effects of the macroscopic pattern on the microstructures “on the fly” can greatly reduce the amount of computer memory in many cases, since only the calculated data for a subset of the microstructures on the substrate may be stored at a given time.
In some specific embodiments of these methods and systems, the subset of surface texture stored in memory is the microscopic structure, and such structure is represented by a relatively small area that is repeated over the full extent of the substrate, and the macroscopic modulation of the structure is applied to each small area “on the fly.”
In one example, a photosensitive material (film) measuring 4 feet by 8 feet is exposed by a scanning laser, using a representation of a pseudorandom microscopic light-diffusing texture that measures 1 mm square, is stored at 2 micron square per pixel resolution, and is repeated (tiled) over the full extent of the film. A desired macroscopic structure, such as a pattern of shaded squares, is stored in a grayscale bitmap file at 200 micron square per pixel resolution. Each area of the film corresponds to a specific pixel in the bitmap file, and during any time that the scanning laser is writing the area of film, the microscopic texture stored in memory is modulated by the brightness value of the bitmap file at the pixel.
In the above example, the bitmap file may cover the entire extent of the photosensitive film, or may itself be smaller than the film (such as 1 foot by 1 foot) and be tiled over the extent of the film. This technique further conserves memory/storage resources.
In an additional aspect, multiple bitmap files may be used at different locations on a film.
In an additional aspect, multiple surface textures may be used at different locations on a film.
In another aspect of these systems and methods, more than one bitmap file or equation or algorithm, etc., or combination thereof may be used to modulate the microscopic surface texture. In one example, a microscopic texture is modulated by a bitmap file across the film in such a way as to produce a more uniform output from a luminaire lit by an array of LED light sources, and is further modulated using a second bitmap file to produce an aesthetically desirable texture.
In other additional aspects, the desired surface texture can be represented not by a bitmap file but by an algorithm or formula or other mathematical representation. This representation can be calculated and applied to the microstructure in advance or “on the fly” as the structures are created.

In any of the embodiments discussed, the macroscopic pattern may be described in many ways, including, but not limited to: bitmap files (any format, compressed or uncompressed), vector graphic files, algorithms, closed form equations, etc.

Other aspects of this invention include systems that create the texture, methods of creating the texture via these systems, the materials (including photosensitive layer) that are used in exposing and possibly developing a master with this surface texture, and the processes, materials, and systems for replicating this surface texture on a substrate.

Various embodiments of the invention, as described herein, can provide unexpected results. In particular, a major function of diffusers for light sources in applications, such as lighting and displays, is to hide the light sources, such as bulbs, fluorescent tubes and/or LEDs, from the viewer; that is, to reduce or prevent the viewer from perceiving the structure or nature of the light source, and/or additionally to reduce or prevent the user from perceiving variations in brightness, such as from center to edges of a light fixture. As described above, application Ser. No. 12/506,915 describes that diffusers with spatial variation can be created, in which the spatial variation caused by light sources can be reduced in a measurable way (e.g., with a camera), in addition to a perceptual way. However, a further unexpected result is that with appropriately chosen patterns or images, a diffuser with visible surface texture can reduce or eliminate a viewer's perception of spatial variations of the light source even if variations are not totally eliminated in a measurable way.

Without wishing to be bound by any theory of operation, this reduction in perception of variation may occur because the patterns obscure or mask the spatial variations of the light source; inhibit or distract the viewer's visual/perceptual systems from detecting these variations; create an optical illusion whereby the user does not perceive the variations; and/or other actual, physical, physiological, or psychological effects that cause a decrease in perception of the spatial variations of the light source due to the diffuser having visible surface texture. In some cases, such as when a diffuser is used over a rectangular array of evenly spaced LED's, a diffuser can be made with visible surface texture that varies in a pattern whose repeating length and width are matched to the repeating length and width of the LED's.

In many cases a diffuser with no visible surface texture can create a look for a luminaire that is deemed by an architect, lighting designer and/or viewer to be aesthetically unacceptable. One example of a look that can be deemed unacceptable is a plain diffuser with no visible surface texture on a luminaire that uses a fluorescent tube, through which a diffuse bright band is visible, making the presence of a fluorescent tube known. A diffuser with visible surface texture used in this same scenario will often produce a result that is deemed acceptable to a viewer, even though the viewer, if asked, would be able to identify that the bright band still exists.

Various embodiments of the invention, as described herein, can provide yet other unexpected results. In particular, a diffuser with visible surface texture can in many cases increase the efficiency, for example as measured in lumens total light output per watt of energy consumed, of a luminaire while still being aesthetically acceptable. Without wishing to be bound by any theory of operation, this unexpected increase in efficiency may be explained as follows: For a given luminaire, it may be possible to create a first uniform diffuser with no visible surface texture, with diffusion sufficiently strong as to hide the light sources to be deemed aesthetically acceptable. Then, a second similar diffuser can be created which has a visible surface texture in which the diffusion varies spatially from a level of diffusion that is equal to that of the first diffuser, to a reduced level of diffusion that has a higher level of light transmission than that of the first diffuser. Thus, this second diffuser has higher total transmission of light than this first diffuser. This second diffuser can thereby provide for a luminaire with higher light output for the same input power. This second diffuser may, despite its increased transmission and/or reduced diffusivity, have acceptable aesthetic appearance for the reasons noted above.

In other embodiments, diffuser sheets are provided that include a pattern or patterns of visible indicia for the purposes of providing one or more of the following potential improvements: (1) better visual appeal of a luminaire, (2) enhancing the lamp or source obscuration quality of the diffuser sheet, (3) increasing the photometric efficiency of the diffuser sheet, (4) improving the manufacturing yield of the diffuser sheet, (5) obscuring or hiding dust, debris, or insects that may collect inside a luminaire during its lifetime. Specifically, patterns may be chosen that provide a visual masking effect to obscure defects or blemishes that may otherwise be visible and unacceptable in an unpatterned diffuser sheet. Diffuser sheets according to these embodiments may be transparent, reflective and/or partially reflective.

In other embodiments, diffuser sheets are provided wherein a pattern of visual surface texture combined with a diffusing texture is disposed on at least one surface of a transparent, reflective and/or partially reflective substrate as a unitary, superimposed layer. The visual pattern of surface texture and the diffusing textures may be individually controlled. The unitary, superimposed layer combines optical diffusion and visual patterning in a single layer.

Yet other embodiments provide methods for forming a unitary, superimposed layer combining a pattern of visual surface texture with a diffusing texture on a transparent, reflective and/or partially reflective substrate. These methods replicate a surface texture via photopolymer cast and cure method, embossing, extrusion and/or the like, wherein the tool or mold used to replicate the surface texture has a unitary, superimposed surface texture that combines the corresponding pattern of visual surface texture with a diffusing texture.

The present invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

When an element is referred to as being coupled or connected to/with another element, it can be directly coupled or connected to/with the other element or intervening elements may also be present. In contrast, if an element is referred to as being directly coupled or connected to/with another element, then no other intervening elements are present. As used herein, the term “and/or” includes any and all combinations of one or more of the associated listed items. The symbol “/” is also used as a shorthand notation for “and/or”.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed above could be termed a second region, layer or section, and similarly, a second region, layer or section could be termed a first region, layer or section without departing from the teachings of the present invention. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A light diffuser comprising:
a substrate including a plurality of diffusing optical microstructures therein and/or thereon, the plurality of diffusing optical microstructures including at least one feature that varies across the substrate so as to produce a visible indicia relative to a viewer of the light diffuser.

2. A light diffuser according to claim 1, wherein the light diffuser is configured to diffuse radiation from a plurality of light sources having predetermined spacing therebetween and wherein the plurality of diffusing optical microstructures also include at least one feature that varies across the substrate as a function of the predetermined spacing between the plurality of light sources.

3. A light diffuser according to claim 1 wherein the plurality of diffusing optical microstructures also include at least one feature that varies deterministically, randomly and/or pseudorandomly across the substrate.

4. A light diffuser according to claim 2 wherein the plurality of diffusing optical microstructures also include at least one feature that varies deterministically, randomly and/or pseudorandomly across the substrate.

5. A light diffuser according to claim 1 wherein the at least one feature comprises a size and/or shape of the plurality of diffusing optical microstructures.

6. A light diffuser according to claim 1 wherein the optical microstructures have a dimension along the substrate that is less than about 100 μm.

7. A light diffuser according to claim 6 wherein the visible indicia has a dimension along the substrate that is greater than about 100 μm.

8. A light diffuser according to claim 1 wherein the at least one feature that varies across the substrate so as to produce a visible indicia relative to a viewer of the light diffuser produces a plurality of continuous and/or discrete levels of brightness in the visible indicia relative to a viewer of the light diffuser.

9. A light diffuser according to claim 1 wherein the plurality of diffusing optical microstructures are on the substrate, the light diffuser further comprising a cladding layer on the plurality of diffusing optical microstructures so as to provide a smooth outer surface on the plurality of diffusing optical microstructures.

10. A light diffuser according to claim 1 wherein the optical microstructures comprise a polymer.

11. A light diffuser according to claim 1 wherein the at least one feature that varies across the substrate so as to provide visible indicia relative to a viewer of the light diffuser comprises at least two features that vary separately across the substrate so as to produce at least two visible indicia at different viewing angles and/or under different conditions relative to a viewer of the light diffuser.

12. A light diffuser according to claim 1 in combination with at least one light source and a housing that is configured to hold the at least one light source and the light diffuser to provide a luminaire.

13. A light transmissive structure comprising:
a substrate including a plurality of optical microstructures therein and/or thereon, the plurality of optical microstructures including at least one feature that varies across the substrate so as to produce a visible indicia relative to a viewer of the light transmissive structure.

14. A light transmissive structure according to claim 13, wherein the light transmissive structure is further configured to diffuse radiation from a plurality of light sources having predetermined spacing therebetween and wherein the plurality of optical microstructures also include at least one feature that varies across the substrate as a function of the predetermined spacing between the plurality of light sources.

15. A light transmissive structure according to claim 13 wherein the plurality of optical microstructures also include at least one feature that varies deterministically, randomly and/or pseudorandomly across the substrate.

16. A light transmissive structure according to claim 14 wherein the plurality of optical microstructures also include at least one feature that varies deterministically, randomly and/or pseudorandomly across the substrate.

17. A light transmissive structure according to claim 13 wherein the at least one feature comprises a size and/or shape of the plurality of optical microstructures.

18. A light transmissive structure according to claim 13 wherein the optical microstructures have a dimension along the substrate that is less than about 100 μm.

19. A light diffuser according to claim 13 wherein the visible indicia has a dimension along the substrate that is greater than about 100 μm.

20. A light transmissive structure according to claim 13 wherein the at least one feature that varies across the substrate so as to provide visible indicia relative to a viewer of the light transmissive structure comprises at least two features that vary separately across the substrate so as to produce at least two visible indicia at different viewing angles and/or under different conditions relative to a viewer of the light transmissive structure.

21. A light transmissive structure according to claim 13 wherein the at least one feature that varies across the substrate so as to produce a visible indicia relative to a viewer of the light diffuser produces a plurality of continuous and/or discrete levels of brightness in the visible indicia relative to a viewer of the light diffuser.

22. A light transmissive structure according to claim 13 in combination with at least one light source and a housing that is configured to hold the at least one light source and the light transmissive structure to provide a luminaire.

23. A method of fabricating a light transmissive structure comprising:
imaging into a photoimageable material an image of a plurality of optical microstructures that include at least one feature that varies across the plurality of optical microstructures; and
using the photoimageable material that was imaged to replicate a plurality of optical microstructures in and/or on a substrate, the plurality of optical microstructures also including at least one feature that varies across the substrate so as to produce a visible indicia relative to a viewer of the light transmissive structure.

24. A method according to claim 23 wherein imaging comprises scanning a laser across the photoimageable material, the laser defining the image of a plurality of optical microstructures that include at least one feature that varies across the plurality of optical microstructures.

25. A method according to claim 23 wherein imaging comprises holographically imaging into a photoimageable material an image of a plurality of optical microstructures that include at least one feature that varies across the plurality of optical microstructures.

26. A method according to claim 23 wherein the light transmissive structure comprises a diffuser.
